(19) United States
(12) Patent Application Publication
(10) Pub. No.: US 2023/0170467 A1
(43) Pub. Date: Jun. 1, 2023

(54) BATTERY ANODE MATERIAL AND METHOD FOR MANUFACTURING THE SAME

(71) Applicant: KOREA PHOTONICS TECHNOLOGY INSTITUTE, Gwangju (KR)

(72) Inventors: Myung Woo SON, Gwangju (KR); Yong Hyun KIM, Gwangju (KR)

(21) Appl. No.: 17/883,650

(22) Filed: Aug. 9, 2022

(30) Foreign Application Priority Data
Nov. 29, 2021 (KR) 10-2021-0166649

(51) Int. Cl. H01M 4/36; H01M 4/04; H01M 4/38; H01M 4/583; H01M 10/0525

(52) U.S. Cl. CPC H01M 4/366; H01M 4/0428; H01M 4/386; H01M 4/583; H01M 10/0525; H01M 2004/027

(57) ABSTRACT

According to an embodiment, an anode active material included in an anode material of a battery comprises a carbon material and a silicon structure attached to the carbon material. The silicon structure includes a silicon nanoparticle, a metal thin film formed on a surface of the silicon nanoparticle, and graphene coated on a surface of the metal thin film.

### CROSS-REFERENCE TO RELATED APPLICATION

This application is based on and claims priority under 35 U.S.C. 119 to Korean Patent Application No. 10-2021-0166649, filed on Nov. 29, 2021, in the Korean Intellectual Property Office, the disclosure of which is herein incorporated by reference in its entirety.

### TECHNICAL FIELD

The disclosure relates to a battery anode material capable of improving the performance and -lifetime of the battery and a method for manufacturing the same.

### DESCRIPTION OF RELATED ART

The description of the Discussion of Related Art section merely provides information that may be relevant to embodiments of the disclosure but should not be appreciated as necessarily constituting the prior art.

A secondary battery or rechargeable battery refers to a battery that may be used semi-permanently by charging/discharging the electricity generated during an oxidation/reduction reaction of substances between the cathode and anode. Secondary batteries are a core component of mobile devices, such as mobile phones and laptops, electric vehicles or energy storage systems (ESSs), and the secondary battery industry is expected to significantly grow in the future.

A lithium-ion battery, a representative secondary battery, is composed of a cathode material, an anode material, a separator, and an electrolyte. The anode material consists of a thin film-shaped conductive anode substrate to increase electrical conductivity, an anode active material fixed on the surface of the anode substrate to receive and discharge lithium ions, and a binder to fix the active material to the anode substrate.

The anode substrate may be formed of a metal (e.g., copper) thin film. As the anode active material, graphite is currently in wide use. As the storage capacity when the graphite-based anode active material is adopted reaches the theoretical limit, there are ongoing research efforts to replace graphite, as the active material, with a high-capacity material, such as silicon or tin, as a new anode material to increase the storage capacity.

However, silicon or metal-based anode active materials experience significant changes in volume during charge/discharge and easily escape off the anode substrate, failing to properly do their functions. Silicon-based active materials may have cracks due to expansion of silicon, deteriorating the reliability of the battery.

An attempt to address these issues is to deposit a metal nano-coating film on the surface of silicon. The metal nano-coating film may suppress volume expansion of silicon and enhance electrical conductivity. However, a reaction may occur between the metal component of the metal nano-coating film and the electrolyte, resulting in changes in the properties and deterioration of electrical conductivity.

Thus, a need exists for an anode active material that is reliable without deterioration of electrical conductivity.

### SUMMARY

An embodiment of the disclosure is to provide a battery anode material that may improve the performance and -lifetime of the battery by preventing cracks in the anode and a method for manufacturing the same.

According to an embodiment, an anode active material included in an anode material of a battery comprises a carbon-material and a silicon structure attached to the carbon material. The silicon structure includes a silicon nanoparticle, a metal thin film formed on a surface of the silicon nanoparticle, and graphene coated on a surface of the metal thin film.

The metal thin film may include at least one or a combination of copper (Cu), nickel (Ni), iron (Fe), platinum (Pt), aluminum (Al), cobalt (Co), ruthenium (Ru), palladium (Pd), chromium (Cr), manganese (Mn), gold (Au), silver (Ag), molybdenum (Mo), rhodium (Rh), tantalum (Ta), titanium (Ti), tungsten (W), uranium (U), vanadium (V), zirconium (Zr), and iridium (Ir).

The carbon fiber may be formed of graphene, activated carbon, or a composite of graphene and activated carbon.

According to an embodiment, an anode active material included in an anode material of a battery comprises a carbon-material and a silicon structure attached to the carbon-material. The silicon structure includes a silicon nanoparticle and graphene positioned outside the silicon nanoparticle, and wherein an empty space is formed between the silicon nanoparticle and the graphene.

According to an embodiment, a method for manufacturing an anode active material included in an anode material of a battery comprises forming a metal thin film on a surface of a silicon structure including a silicon nanoparticle by immersing the silicon structure in a metal plating solution, coating graphene on the metal thin film in a preset environment, and mixing the graphene-coated silicon structure with a carbon material.

The graphene may include at least one selected from the group consisting of natural graphite, synthetic graphite, highly ordered pyrolytic graphite (HOPG), activated carbon or activated graphite, carbon monoxide, carbon dioxide, methane, ethane, ethylene, methanol, ethanol, acetylene, propane, propylene, butane, butadiene, pentane, pentene, cyclopentadiene, hexane, cyclohexane, benzene, pyridine, toluene, polymethyl methacrylate (PMMA), polystyrene, polyacrylonitrile (PAN), methylnaphthalene with a polycyclic aromatic hydrocarbon structure, hexabromobenzene, naphthalene, terphenyl, pentachloropyridine, tetrabromothiophene, benzopyrene, azulene, trimethylnaphthalene, acenaphthene, acenaphthylene, anthracene, fluorene, phenalene, phenanthrene, benz(a)anthracene, benzo(a)fluorene, benzo(c)phenanthrene, chrysene, fluoranthene, pyrene, tetracene, triphenylene, benz(e)acephenanthrylene, benzofluoranthene, dibenzanthracene, olympicene, pentacene, perylene, picene, tetraphenylene, zethrene, ovalene, kekulene, hexacene, heptacene, diindenoperylene, dicoronylene, coronene, corannulene, benzo(ghi)perylene, anthanthrene, hexamethyl-dihydro-4H-benzoquinolizinoacridine, 4H-benzoquinolizinoacridinetrione), and hexaazatriphenylene-hexacarbonitrile.

The preset environment may be an environment having a predetermined temperature range.

The predetermined temperature range may be 25° C. to 400° C. .

Forming the metal thin film may include forming the metal thin film by coating a metal on the surface of the silicon structure instead of immersing the silicon structure in the metal plating solution.

Forming the metal thin film may include forming the metal thin film by depositing, by chemical vapor deposition, the metal on the surface of the silicon structure.

The method may further comprise immersing the graphene-coated silicon structure in a metal etchant.

According to embodiments, it is possible to improve the performance and lifetime of the battery by preventing cracks in the anode.

### BRIEF DESCRIPTION OF THE DRAWINGS

A more complete appreciation of the disclosure and many of the attendant aspects thereof will be readily obtained as the same becomes better understood by reference to the following detailed description when considered in connection with the accompanying drawings, wherein:

FIG. 1 is a flowchart illustrating a method for manufacturing an anode active material according to a first embodiment of the disclosure;

FIG. 2 is a view illustrating an anode active material according to the first embodiment of the disclosure;

FIG. 3 is a view illustrating silicon nanoparticles according to an embodiment of the disclosure;

FIG. 4 is a view illustrating a method for forming a metal thin film on silicon nanoparticles according to an embodiment of the disclosure;

FIG. 5 is a view illustrating another method for forming a metal thin film on silicon nanoparticles according to an embodiment of the disclosure;

FIG. 6 is a view illustrating silicon nanoparticles on which a metal thin film is formed according to the first embodiment of the disclosure;

FIG. 7 is a view illustrating silicon nanoparticles with a metal thin film coated with graphene according to the first embodiment of the disclosure;

FIG. 8 is a flowchart illustrating a method for manufacturing an anode active material according to a second embodiment of the disclosure; and

FIG. 9 is a view illustrating an anode active material according to the second embodiment of the disclosure.

### DETAILED DESCRIPTION

Various changes may be made to the disclosure, and the disclosure may come with a diversity of embodiments. Some embodiments of the disclosure are shown and described in connection with the drawings. However, it should be appreciated that the disclosure is not limited to the embodiments, and all changes and/or equivalents or replacements thereto also belong to the scope of the disclosure. Similar reference denotations are used to refer to similar elements throughout the drawings.

The terms “first” and “second” may be used to describe various components, but the components should not be limited by the terms. The terms are used to distinguish one component from another. For example, a first component may be denoted a second component, and vice versa without departing from the scope of the disclosure. The term “and/or” may denote a combination(s) of a plurality of related items as listed or any of the items.

It will be understood that when an element or layer is referred to as being “on,” “connected to,” “coupled to,” or “adjacent to” another element or layer, it can be directly on, connected, coupled, or adjacent to the other element or layer, or intervening elements or layers may be present. In contrast, when a component is “directly connected to” or “directly coupled to” another component, no other intervening components may intervene therebetween.

The terms as used herein are provided merely to describe some embodiments thereof, but not to limit the disclosure. As used herein, the singular forms “a,” “an,” and “the” are intended to include the plural forms as well, unless the context clearly indicates otherwise. As used herein, the term “comprise,” “include,” or “have” should be appreciated not to preclude the presence or addability of features, numbers, steps, operations, components, parts, or combinations thereof as set forth herein.

Unless otherwise defined, all terms including technical and scientific terms used herein have the same meaning as commonly understood by one of ordinary skill in the art to which the embodiments of the disclosure belong.

It will be further understood that terms, such as those defined in commonly used dictionaries, should be interpreted as having a meaning that is consistent with their meaning in the context of the relevant art and will not be interpreted in an idealized or overly formal sense unless expressly so defined herein.

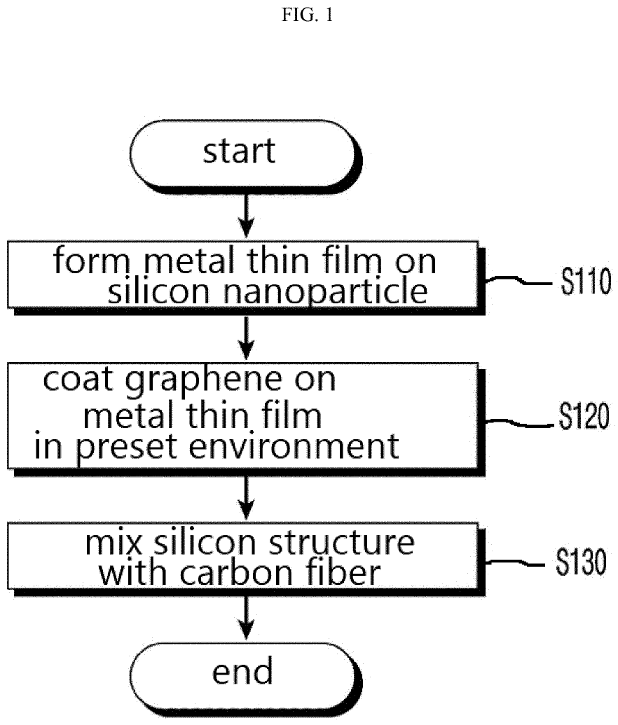

The components, processes, steps, or methods according to embodiments of the disclosure may be shared as long as they do not technically conflict with each other. FIG. 1 is a flowchart illustrating a method for manufacturing an anode active material according to a first embodiment of the disclosure. The anode active material manufacturing method shown in FIG. 1 may be performed by an anode active material manufacturing device.

A metal thin film is formed on the silicon nanoparticles (S110).

As in the prior art, silicon nanoparticles are used as the anode active material. However, when only silicon nanoparticles are used, the volume of the silicon nanoparticles increases or decreases when the silicon particles are bonded with or detached from lithium ions, as described above. Accordingly, the silicon nanoparticles may be damaged. Further, due to their low electrical conductivity, the silicon nanoparticles may reduce the performance of the battery.

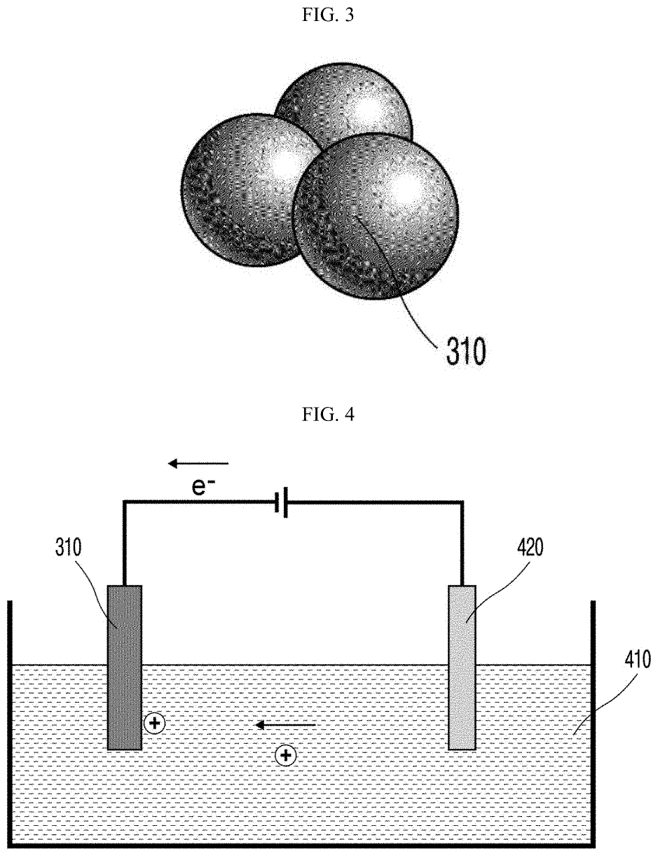

Accordingly, the metal thin film is formed on the silicon nanoparticles, forming a core-shell structure. The formation of the metal thin film may address the low conductivity of silicon. The metal for forming the metal thin film may be, or include, at least one or a combination of copper (Cu), nickel (Ni), iron (Fe), platinum (Pt), aluminum (Al), cobalt (Co), ruthenium (Ru), palladium (Pd), chromium (Cr), manganese (Mn), gold (Au), silver (Ag), molybdenum (Mo), rhodium (Rh), tantalum (Ta), titanium (Ti), tungsten (W), uranium (U), vanadium (V), zirconium (Zr), and iridium (Ir). The process and result of forming the metal into the metal thin film for the silicon nanoparticles are shown in FIGS. 3 to 6.

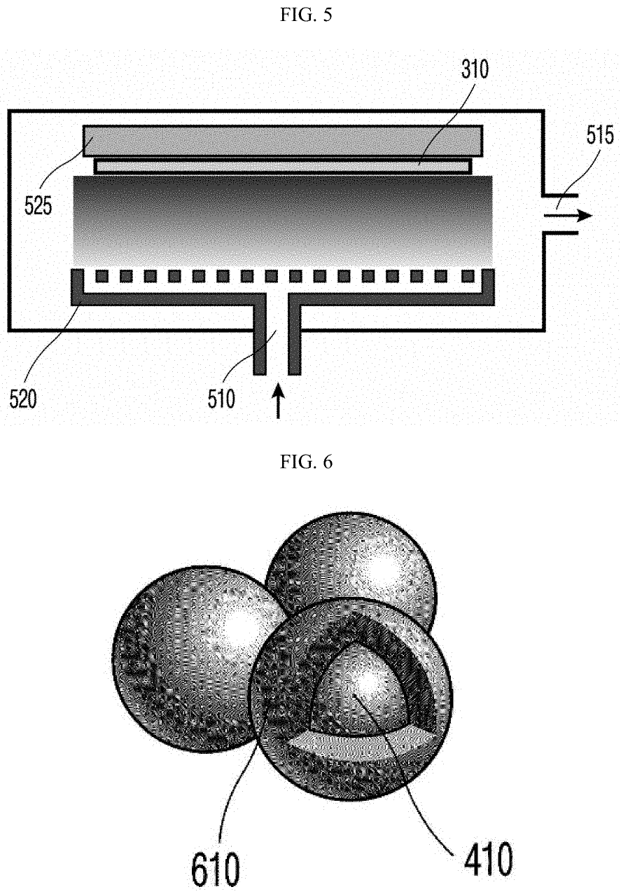

FIG. 3 is a view illustrating silicon nanoparticles according to an embodiment of the disclosure. FIG. 4 is a view illustrating a method for forming a metal thin film on silicon nanoparticles according to an embodiment of the disclosure. FIG. 5 is a view illustrating another method for forming a metal thin film on silicon nanoparticles according to an embodiment of the disclosure. FIG. 6 is a view illustrating silicon nanoparticles on which a metal thin film is formed according to the first embodiment of the disclosure.

As illustrated in FIG. 3, a silicon nanoparticle powder 310 is prepared. The silicon nanoparticle powder 310 may be immersed in a metal plating solution as shown in FIG. 5, and a metal thin film may be formed on the silicon nanoparticles.

Referring to FIG. 4, an anode 310 formed of silicon nanoparticles is immersed in the metal plating solution 410 for the metal thin film. In this case, a cathode 420 formed of a metal is also immersed in the plating solution 410. When electricity is applied between the electrodes 310 and 410, the metal cations from the cathode 420 forms a thin film on the surface of the anode 310. During the process, a metal thin film may be formed on the surface of the silicon nanoparticles 310.

Alternatively, a metal thin film may be formed on the surface of the silicon nanoparticles by chemical vapor deposition of metal particles on the surface of silicon nanoparticles as shown in FIG. 5.

Metal particles are introduced through a gas inlet 510 and are disposed on the electrodes 520 and 525 in the reactor. A silicon nanoparticle component 310 is disposed as one electrode 525. Accordingly, the metal particle component is deposited on the surface of the silicon nanoparticle component 310, forming a metal thin film.

FIG. 5 illustrates an example of chemical vapor deposition, but without limitations thereto, other methods, such as thermal chemical vapor deposition (TCVD), rapid thermal chemical vapor deposition (RTCVD), inductively coupled plasma-chemical vapor deposition (ICP-CVD), low pressure chemical vapor deposition (LPCVD), atmospheric pressure chemical vapor deposition (APCVD), metal organic chemical vapor deposition (MOCVD), or plasma-enhanced chemical vapor deposition (PECVD).

According to the process, as shown in FIG. 6, a metal thin film 610 may be formed on the surface of the silicon nanoparticles 310.

Referring back to FIG. 1, graphene is coated on the metal thin film 610 in a preset environment (S120). As the graphene is coated on the metal thin film 610, it is possible to prevent degradation of the properties of the metal and to enhance mechanical strength. Graphene has high crystallinity and may block the penetration of the electrolyte. Accordingly, when graphene is coated on the metal thin film 610, the graphene prevents the penetration of the electrolyte into the inside of the graphene, thereby preventing damage to the metal thin film by the electrolyte. Further, since graphene serves as a buffer for volume expansion of the silicon particles, it is possible to prevent damage to the silicon particles due to the volume change in the silicon particles.

Graphene may be coated on the metal thin film by various chemical vapor deposition methods. However, graphene may be difficult to form into a high-quality carbon film. In an embodiment of the disclosure, graphene may be coated on the metal thin film 610 by being deposited in a preset environment.

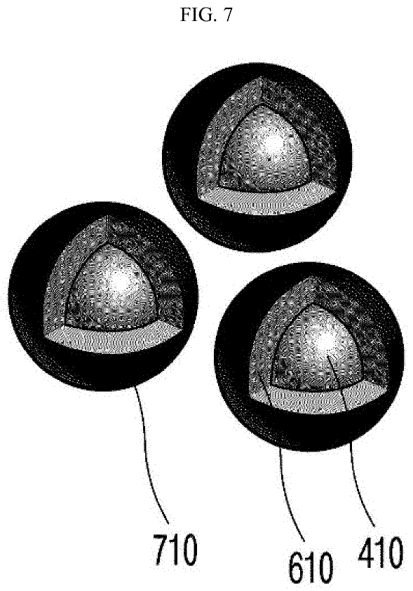

The preset environment may be an environment having a low temperature of 25° C. to 400° C. Typically, deposition of graphene proceeds at a high temperature. However, in an embodiment of the disclosure, graphene implemented of the component described below is adopted, so that the deposition may be achieved even at a low temperature of 25° C. to 400° C. The graphene may be, or include, at least one selected from the group consisting of natural graphite, synthetic graphite, highly ordered pyrolytic graphite (HOPG), activated carbon or activated graphite, carbon monoxide, carbon dioxide, methane, ethane, ethylene, methanol, ethanol, acetylene, propane, propylene, butane, butadiene, pentane, pentene, cyclopentadiene, hexane, cyclohexane, benzene, pyridine, toluene, polymethyl methacrylate (PMMA), polystyrene, polyacrylonitrile (PAN), methylnaphthalene with a polycyclic aromatic hydrocarbon structure, hexabromobenzene, naphthalene, terphenyl, pentachloropyridine, tetrabromothiophene, benzopyrene, azulene, trimethylnaphthalene, acenaphthene, acenaphthylene, anthracene, fluorene, phenalene, phenanthrene, benz(a)anthracene, benzo(a)fluorene, benzo(c)phenanthrene, chrysene, fluoranthene, pyrene, tetracene, triphenylene, benz(e)acephenanthrylene, benzofluoranthene, dibenzanthracene, olympicene, pentacene, perylene, picene, tetraphenylene, zethrene, ovalene, kekulene, hexacene, heptacene, diindenoperylene, dicoronylene, coronene, corannulene, benzo(ghi)perylene, anthanthrene, hexamethyl-dihydro-4H-benzoquinolizinoacridine, 4H-benzoquinolizinoacridinetrione), and hexaazatriphenylene-hexacarbonitrile. As the graphene of the component is chemically deposited, the graphene may be coated on the metal thin film even in the preset environment, i.e., an environment having a low temperature of 25° C. to 400° C. Accordingly, the graphene is coated as shown in FIG. 7.

FIG. 7 is a view illustrating silicon nanoparticles with a metal thin film coated with graphene according to the first embodiment of the disclosure.

A metal thin film 610 is formed on the surface of the silicon nanoparticles 310, and graphene 710 is coated on the metal thin film 610.

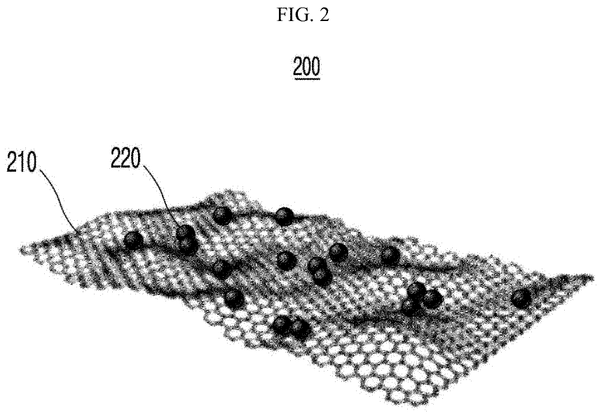

Referring back to FIG. 1, the graphene 710-coated silicon structure and carbon-material are mixed (S130). The silicon structure in the powder state and the carbon material to support the silicon structure are mixed (milled) into the powder state. The carbon material may be activated carbon, graphene, or a composite thereof. When both the components (i.e., the silicon structure and the carbon powder) are mixed, an anode active material as shown in FIG. 2 is formed.

FIG. 2 is a view illustrating an anode active material according to the first embodiment of the disclosure.

The anode active material 200 is formed with the silicon structures 220 attached to the surface of the carbon material 210 by mixing. By being formed of the carbon material 210 and the silicon structures 220 attached to the surface of the carbon material 210, the anode active material 200 may secure the above-described effects.

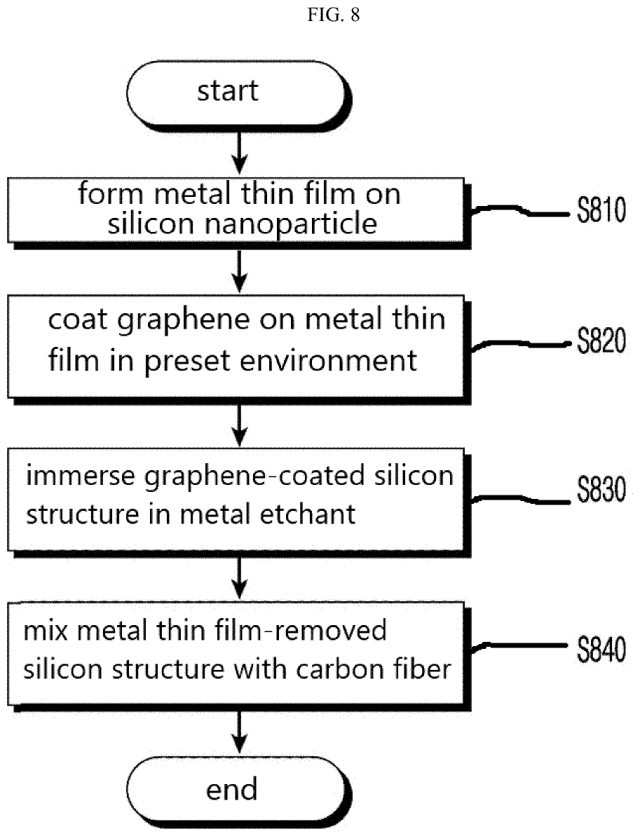

FIG. 8 is a flowchart illustrating a method for manufacturing an anode active material according to a second embodiment of the disclosure.

A metal thin film is formed on the silicon nanoparticles (S810).

Graphene is coated on the metal thin film 610 in a preset environment (S820).

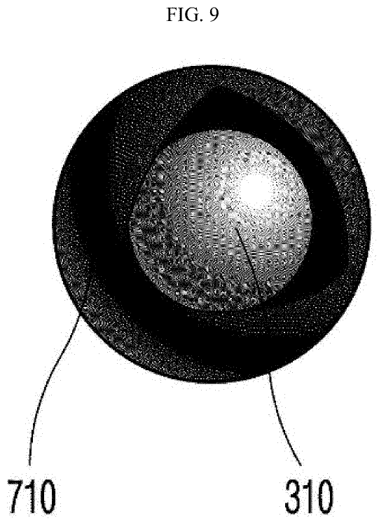

The graphene-coated silicon structure is immersed in a metal etchant (S830). As shown in FIG. 7, the graphene-coated silicon structure is immersed in a metal etchant. As the metal etchant, various etchants, such as ammonium hydroxide/hydrogen peroxide solution, iron(III) nitrate hydrate aqueous solution, phosphoric acid/nitric acid/acetic acid aqueous solution, iron chloride etchant, copper chloride etchant or hydrogen peroxide-based etchant may be used. Accordingly, only the metal thin film 610 formed between the silicon nanoparticles 310 and the graphene 710 is dissolved by the etchant. As the metal thin film 610 is dissolved, the silicon structure has the shape shown in FIG. 9.

FIG. 9 is a view illustrating an anode active material according to the second embodiment of the disclosure.

As described above, since the metal thin film 610 is dissolved, a space between the silicon nanoparticles 310 and the graphene 710 is generated. Due to the dissolution of the metal thin film 610, the overall electrical conductivity of the anode active material is somewhat decreased, but since an empty space is formed, the silicon nanoparticles, which expand when ionically bonded, may expand to the graphene 710 without damage, leading to structural stability.

Referring back to FIG. 8, the metal thin film-removed silicon structure and the carbon material are mixed (S840).

Although FIGS. 1 and 9 illustrate that the steps are sequentially performed, this merely provides an embodiment of the disclosure. It would readily be appreciated by a skilled artisan that the steps of FIG. 5 are not limited to the order shown but may rather be performed in a different order, one or more of the steps may simultaneously be performed, or other various modifications or changes may be made thereto without departing from the scope of the disclosure

The steps or processes described above in connection with FIGS. 1 and 9 may be implemented as computer-readable code in a recording medium. The computer-readable recording medium includes all types of recording devices storing data readable by a computer system. The computer-readable recording medium includes a storage medium, such as a magnetic storage medium (e.g., a ROM, a floppy disk, or a hard disk) or an optical reading medium (e.g., a CD-ROM or a DVD). Further, the computer-readable recording medium may be distributed to computer systems connected via a network, and computer-readable codes may be stored and executed in a distributed manner.

The above-described embodiments are merely examples, and it will be appreciated by one of ordinary skill in the art various changes may be made thereto without departing from the scope of the disclosure. Accordingly, the embodiments set forth herein are provided for illustrative purposes, but not to limit the scope of the disclosure, and should be appreciated that the scope of the disclosure is not limited by the embodiments. The scope of the disclosure should be construed by the following claims, and all technical spirits within equivalents thereof should be interpreted to belong to the scope of the disclosure.

What is claimed is:

1. An anode active material included in an anode material of a battery, the anode active material comprising:
a carbon material; and
a silicon structure attached to the carbon material, wherein
the silicon structure includes:
a silicon nanoparticle;
a metal thin film formed on a surface of the silicon nanoparticle; and
graphene coated on a surface of the metal thin film.

2. The anode active material of claim 1, wherein the metal thin film includes at least one or a combination of copper (Cu), nickel (Ni), iron (Fe), platinum (Pt), aluminum (Al), cobalt (Co), ruthenium (Ru), palladium (Pd), chromium (Cr), manganese (Mn), gold (Au), silver (Ag), molybdenum (Mo), rhodium (Rh), tantalum (Ta), titanium (Ti), tungsten (W), uranium (U), vanadium (V), zirconium (Zr), and iridium (Ir).

3. The anode active material of claim 1, wherein the carbon material is formed of graphene, activated carbon, or a composite of graphene and activated carbon.

4. An anode active material included in an anode material of a battery, the anode active material comprising:
a carbon material; and
a silicon structure attached to the carbon material, wherein the silicon structure includes:
a silicon nanoparticle; and
graphene positioned outside the silicon nanoparticle, and wherein an empty space is formed between the silicon nanoparticle and the graphene.

5. A method for manufacturing an anode active material included in an anode material of a battery, the method comprising:
forming a metal thin film on a surface of a silicon structure including a silicon nanoparticle by immersing the silicon structure in a metal plating solution;
coating graphene on the metal thin film in a preset environment; and
mixing the graphene-coated silicon structure with a carbon material.

6. The method of claim 5, wherein the graphene includes at least one selected from the group consisting of natural graphite, synthetic graphite, highly ordered pyrolytic graphite (HOPG), activated carbon or activated graphite, carbon monoxide, carbon dioxide, methane, ethane, ethylene, methanol, ethanol, acetylene, propane, propylene, butane, butadiene, pentane, pentene, cyclopentadiene, hexane, cyclohexane, benzene, pyridine, toluene, polymethyl methacrylate (PMMA), polystyrene, polyacrylonitrile (PAN), methylnaphthalene with a polycyclic aromatic hydrocarbon structure, hexabromobenzene, naphthalene, terphenyl, pentachloropyridine, tetrabromothiophene, benzopyrene, azulene, trimethylnaphthalene, acenaphthene, acenaphthylene, anthracene, fluorene, phenalene, phenanthrene, benz(a)anthracene, benzo(a)fluorene, benzo(c)phenanthrene, chrysene, fluoranthene, pyrene, tetracene, triphenylene, benz(e)acephenanthrylene, benzofluoranthene, dibenzanthracene, olympicene, pentacene, perylene, picene, tetraphenylene, zethrene, ovalene, kekulene, hexacene, heptacene, diindenoperylene, dicoronylene, coronene, corannulene, benzo(ghi)perylene, anthanthrene, hexamethyl-dihydro-4H-benzoquinolizinoacridine, 4H-benzoquinolizinoacridinetrione), and hexaazatriphenylene-hexacarbonitrile.

7. The method of claim 6, wherein the preset environment is an environment having a predetermined temperature range.

8. The method of claim 7, wherein the predetermined temperature range is 25° C. to 400° C.

9. The method of claim 5, wherein forming the metal thin film includes forming the metal thin film by coating a metal on the surface of the silicon structure instead of immersing the silicon structure in the metal plating solution.

10. The method of claim 9, wherein forming the metal thin film includes forming the metal thin film by depositing, by chemical vapor deposition, the metal on the surface of the silicon structure.

11. The method of claim 5, further comprising immersing the graphene-coated silicon structure in a metal etchant.
